(19) United States
(12) Patent Application Publication
(10) Pub. No.: US 2026/0282518 A1
(43) Pub. Date: Sep. 17, 2026

(54) SEMICONDUCTOR DEVICE

(71) Applicant: Nuvoton Technology Corporation Japan, Kyoto (JP)

(72) Inventors: Takeshi IMAMURA, Kyoto (JP); Ryouichi AJIMOTO, Kyoto (JP); Kouki YAMAMOTO, Kyoto (JP); Akira KIMURA, Kyoto (JP)

(21) Appl. No.: 19/675,948

(22) Filed: May 13, 2026

Related U.S. Application Data
(63) Continuation of application No. PCT/JP2025/020700, filed on Jun. 9, 2025.
(60) Provisional application No. 63/658,732, filed on Jun. 11, 2024.

(51) Int. Cl. H10D 84/00

(52) U.S. Cl. CPC H10D 84/146

(57) ABSTRACT

A semiconductor device includes: a semiconductor layer including a semiconductor substrate of a first conductivity type and a low-concentration impurity layer of the first conductivity type, the semiconductor substrate containing a first concentration of an impurity, the low-concentration impurity layer being in contact with a top surface of the semiconductor substrate and containing a second concentration of an impurity, the second concentration being lower than the first concentration; a first vertical metal-oxide-semiconductor (MOS) transistor and a second vertical MOS transistor that share the semiconductor substrate as a common drain region; and a first Schottky barrier diode that is connected in parallel with a body diode of the first vertical MOS transistor in a same forward direction, the low-concentration impurity layer serving as a cathode of the first Schottky barrier diode when the first conductivity type is n-type, and as an anode when the first conductivity type is p-type.

### CROSS REFERENCE TO RELATED APPLICATIONS

This is a continuation application of PCT International Patent Application No. PCT/JP2025/020700 filed on June 9, 2025, designating the United States of America, which is based on and claims priority of U.S. Provisional Patent Application No. 63/658732 filed on June 11, 2024. The entire disclosures of the above-identified applications, including the specifications, drawings and claims are incorporated herein by reference in their entirety.

### FIELD

The present disclosure relates to a semiconductor device including a vertical metal-oxide-semiconductor (MOS) transistor.

### BACKGROUND

Conventionally, a semiconductor device that includes two vertical MOS transistors that share a semiconductor substrate as a common drain region is known.

In addition, conventionally, a technique is known in which a Schottky barrier diode having the same forward direction as the body diode of a vertical MOS transistor is connected in parallel with the body diode of the vertical MOS transistor, thereby reducing the forward voltage between a node connected to the anode of the body diode of the vertical MOS transistor and a node connected to the cathode of the body diode of the vertical MOS transistor to be lower than the forward voltage of the body diode of the vertical MOS transistor alone.

### Citation List

### Patent Literature

PTL 1: Japanese Unexamined Patent Application Publication No. 2002-203966

### SUMMARY

### Technical Problem

Conventionally, in a semiconductor device that includes two vertical MOS transistors that share a semiconductor substrate as a common drain region (hereinafter also referred to as “conventional dual-configuration semiconductor device”), when a forward voltage between a node connected to the anode of the body diode of one of the vertical MOS transistors and a node connected to the cathode of the body diode of the one of the vertical MOS transistors is to be reduced, it is necessary to realize the reduction of the forward voltage by connecting a discrete Schottky barrier diode having the same forward direction as the body diode of the one of the vertical MOS transistors in parallel with the body diode of the vertical MOS transistor.

For this reason, it is necessary to provide a discrete Schottky barrier diode separately in proximity to the conventional dual-configuration semiconductor device.

As a result, a total number of elements increases compared to when the conventional dual-configuration semiconductor device is used alone.

In view of the above, the present disclosure provides a semiconductor device that is, compared to when the conventional dual-configuration semiconductor device is used alone, capable of reducing the forward voltage between a node connected to the anode of the body diode of one of the two vertical MOS transistors that share a semiconductor substrate as a common drain region and a node connected to the cathode of the body diode of the one of the two vertical MOS transistors, without increasing the total number of elements.

### Solution to Problem

A semiconductor device according to one aspect of the present disclosure includes a semiconductor layer including a semiconductor substrate of a first conductivity type and a low-concentration impurity layer of the first conductivity type, the semiconductor substrate containing a first concentration of an impurity, the low-concentration impurity layer being in contact with a top surface of the semiconductor substrate and containing a second concentration of an impurity, the second concentration being lower than the first concentration; a first vertical metal-oxide-semiconductor (MOS) transistor and a second vertical MOS transistor that share the semiconductor substrate as a common drain region; and a first Schottky barrier diode that is connected in parallel with a body diode of the first vertical MOS transistor in a same forward direction. In the semiconductor device, in the first Schottky barrier diode, the low-concentration impurity layer serves as a cathode of the first Schottky barrier diode when the first conductivity type is n-type, and serves as an anode of the first Schottky barrier diode when the first conductivity type is p-type.

### Advantageous Effects

With the semiconductor device according to one aspect of the present disclosure, it is possible to provide a semiconductor device that is, compared to when the conventional dual-configuration semiconductor device is used alone, capable of reducing the forward voltage between a node connected to the anode of the body diode of one of the two vertical MOS transistors that share a semiconductor substrate as a common drain region and a node connected to the cathode of the body diode of the one of the two vertical MOS transistors, without increasing the total number of elements.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view schematically illustrating an example of a configuration of a semiconductor device according to Embodiment 1.

FIG. 2 is a cross-sectional view schematically illustrating an example of the configuration of the semiconductor device according to Embodiment 1.

FIG. 3 is a circuit diagram of the semiconductor device according to Embodiment 1.

FIG. 4 is an enlarged cross-sectional perspective view schematically illustrating an example of a configuration around first gate trenches according to Embodiment 1.

FIG. 5 is an enlarged cross-sectional perspective view schematically illustrating an example of a configuration around second gate trenches according to Embodiment 1.

FIG. 6 is a plan view schematically illustrating a positional relationship between a first body region, a second body region, and a first Schottky junction region, according to Embodiment 1.

FIG. 7A is a plan view schematically illustrating a positional relationship between the first body region, the second body region, and the first Schottky junction region, according to Embodiment 1.

FIG. 7B is a plan view schematically illustrating a positional relationship between the first body region, the second body region, and the first Schottky junction region, according to Embodiment 1.

FIG. 7C is a plan view schematically illustrating a positional relationship between the first body region, the second body region, and the first Schottky junction region, according to Embodiment 1.

FIG. 8 is an enlarged cross-sectional view schematically illustrating an example of a configuration of a first electrode according to Embodiment 1.

FIG. 9 is a plan view schematically illustrating an example of a configuration of a semiconductor device according to Embodiment 2.

FIG. 10 is a cross-sectional view schematically illustrating an example of the configuration of the semiconductor device according to Embodiment 2.

FIG. 11 is a circuit diagram of the semiconductor device according to Embodiment 2.

FIG. 12 is a plan view schematically illustrating an example of a configuration of the semiconductor device according to Embodiment 2.

### DESCRIPTION OF EMBODIMENTS

### Circumstances Leading to One Aspect of the Present Disclosure

The inventors have conceived an idea that if, in addition to two vertical MOS transistors that share a semiconductor substrate as a common drain region, a Schottky barrier diode having the same forward direction as the body diode of one of the two vertical MOS transistors could be implemented inside a semiconductor device, it would be possible to implement a semiconductor device capable of reducing the forward voltage between a node connected to the anode of the body diode of one of the two vertical MOS transistors and a node connected to the cathode of the body diode of the one of the two vertical MOS transistors, without increasing the total number of elements compared to when the conventional dual-configuration semiconductor device is used alone.

The inventors have repeated experiments and analysis, based on this idea, to arrive at a semiconductor device according to the present disclosure described below.

A semiconductor device according to one aspect of the present disclosure includes a semiconductor layer including a semiconductor substrate of a first conductivity type and a low-concentration impurity layer of the first conductivity type, the semiconductor substrate containing a first concentration of an impurity, the low-concentration impurity layer being in contact with a top surface of the semiconductor substrate and containing a second concentration of an impurity, the second concentration being lower than the first concentration; a first vertical metal-oxide-semiconductor (MOS) transistor and a second vertical MOS transistor that share the semiconductor substrate as a common drain region; and a first Schottky barrier diode that is connected in parallel with a body diode of the first vertical MOS transistor in a same forward direction. In the semiconductor device, in the first Schottky barrier diode, the low-concentration impurity layer serves as a cathode of the first Schottky barrier diode when the first conductivity type is n-type, and serves as an anode of the first Schottky barrier diode when the first conductivity type is p-type.

The semiconductor device configured as above includes inside thereof: two vertical MOS transistors that share the semiconductor substrate as a common drain region; and a Schottky barrier diode that is connected in parallel with the body diode of one of the vertical MOS transistors in the same forward direction.

Accordingly, with the semiconductor device configured as above, it is possible to provide a semiconductor device that is, compared to when the conventional dual-configuration semiconductor device is used alone, capable of reducing the forward voltage between a node connected to the anode of the body diode of one of the two vertical MOS transistors sharing a semiconductor substrate as a common drain region and a node connected to the cathode of the body diode of the one of the two vertical MOS transistors, without increasing the total number of elements.

In addition, a Schottky barrier diode that is connected in parallel with a body diode of the second vertical MOS transistor in a same forward direction may be absent

With the above-described configuration, it is possible to inhibit an increase in size of the semiconductor device, compared to the case of having the configuration in which the Schottky barrier diode that is connected in parallel with the body diode of the other vertical MOS transistor in the same forward direction is further provided.

In addition, a total gate width of the first vertical MOS transistor and a total gate width of the second vertical MOS transistor may be equal to each other.

With the above-described configuration, it is possible to relatively easily make the characteristic of the first vertical MOS transistor and the characteristic of the second vertical MOS transistor equal to each other.

In addition, a first electrode that functions as a source electrode of the first vertical MOS transistor, and functions (i) as an anode electrode of the first Schottky barrier diode when the first conductivity type is n-type and (ii) as a cathode electrode of the first Schottky barrier diode when the first conductivity type is p-type; and a second electrode that functions as a source electrode of the second vertical MOS transistor may be further included, and an area of the first electrode may be larger than an area of the second electrode in a plan view of the semiconductor device.

With the above-described configuration, it is possible to inhibit an increase in size of the semiconductor device, compared to the case of having the configuration in which an electrode that functions as a source electrode of the first vertical MOS transistor and an electrode that functions an anode electrode or a cathode electrode of the first Schottky barrier diode are provided as mutually different electrodes.

In addition, on a top surface of the semiconductor device, one or more first source pads that function as source pads of the first vertical MOS transistor; and one or more second source pads that function as source pads of the second vertical MOS transistor may be further included, the one or more second source pads being same in a total number as the one or more first source pads. The semiconductor device may have a rectangular shape including a first side and a second side parallel to each other in the plan view, and in the plan view, the one or more first source pads and the one or more second source pads may be positioned point-symmetrically with a center of the semiconductor device as a center of symmetry, or positioned line-symmetrically with a straight line connecting a midpoint of the first side and a midpoint of the second side as an axis of symmetry.

With the above-described configuration, it is possible to inhibit the occurrence of defects such as a contact failure when mounting the semiconductor device on a mounting substrate. In addition, in bidirectional conduction of the conduction direction from the first vertical MOS transistor toward the second vertical MOS transistor and the conduction direction from the second vertical MOS transistor toward the first vertical MOS transistor, it is possible to inhibit current concentration and/or heat concentration from occurring disproportionately in either one of the vertical MOS transistors.

In addition, a first body region of a second conductivity type that is provided in the low-concentration impurity layer, and functions as a body region of the first vertical MOS transistor may be further included, the second conductivity type being different from the first conductivity type. The first electrode may include: a Schottky junction region that forms a Schottky junction with a top surface of the semiconductor layer within a region that does not encompass even a part of the first body region in the plan view; and an ohmic contact region that forms an ohmic contact with the top surface of the semiconductor layer within a region that does not include even a part of a portion that does not encompass the first body region in the plan view. The first electrode may include a plurality of conductive layers including (i) a Schottky junction layer that forms a Schottky junction with the top surface of the semiconductor layer in the Schottky junction region and (ii) an ohmic contact layer that forms an ohmic contact with the top surface of the semiconductor layer in the ohmic contact region. A metal contained in the Schottky junction layer and a metal contained in the ohmic contact layer may be identical to each other.

With the above-described configuration, it is possible to further simplify the manufacturing process compared to the case where the metal contained in the Schottky junction layer and the metal contained in the ohmic contact layer are different from each other.

In addition, a first body region of a second conductivity type that is provided in the low-concentration impurity layer, and functions as a body region of the first vertical MOS transistor may be further included, the second conductivity type being different from the first conductivity type. The first electrode may include: a Schottky junction region that forms a Schottky junction with a top surface of the semiconductor layer within a region that does not encompass even a part of the first body region in the plan view; and an ohmic contact region that forms an ohmic contact with the top surface of the semiconductor layer within a region that does not include even a part of a portion that does not encompass the first body region in the plan view. The first electrode may include a plurality of conductive layers including (i) a Schottky junction layer that forms a Schottky junction with the top surface of the semiconductor layer in the Schottky junction region and (ii) an ohmic contact layer that forms an ohmic contact with the top surface of the semiconductor layer in the ohmic contact region. A metal contained in the Schottky junction layer and a metal contained in the ohmic contact layer may be different from each other.

With the above-described configuration, it is possible to enhance the characteristic of the first Schottky barrier diode, in particular the characteristic related to the forward voltage, a leakage current, and so forth, compared to the case where the metal contained in the Schottky junction layer and the metal contained in ohmic contact layer are identical to each other.

In addition, the semiconductor device may have a rectangular shape including a first side and a second side parallel to each other in the plan view. The semiconductor device may further include: a first body region of a second conductivity type that is provided in the low-concentration impurity layer, and functions as a body region of the first vertical MOS transistor, the second conductivity type being different from the first conductivity type; and a second body region of the second conductivity type that is provided in the low-concentration impurity layer, and functions as a body region of the second vertical MOS transistor; and an opposing region that: includes a center of the semiconductor device, a midpoint of the first side, and a midpoint of the second side; and is continuous with a constant width from the first side to the second side in the plan view, the opposing region being located between the first body region and the second body region and not including even a part of the first body region or the second body region. An entirety of a region that forms a Schottky junction in the first Schottky barrier diode may be encompassed within the opposing region in the plan view.

With the above-described configuration, it is possible to relatively easily make the characteristic of the first vertical MOS transistor and the characteristic of the second vertical MOS transistor equal to each other.

In addition, the semiconductor device may have a rectangular shape including a first side and a second side parallel to each other in the plan view. The semiconductor device may further include: a first body region of a second conductivity type that is provided in the low-concentration impurity layer, and functions as a body region of the first vertical MOS transistor, the second conductivity type being different from the first conductivity type; a second body region of the second conductivity type that is provided in the low-concentration impurity layer, and functions as a body region of the second vertical MOS transistor; and an opposing region that: includes a center of the semiconductor device, a midpoint of the first side, and a midpoint of the second side; and is continuous with a finite width from the first side to the second side in the plan view, the opposing region being located between the first body region and the second body region and not including even a part of the first body region or the second body region. The opposing region may include a central region whose width in a direction parallel to the first side and the second side is continuous with a maximum width of the opposing region in the direction, and an entirety of a region that forms a Schottky junction in the first Schottky barrier diode may be encompassed within the central region.

With the above-described configuration, it is possible to relatively easily make the characteristic of the first vertical MOS transistor and the characteristic of the second vertical MOS transistor equal to each other.

In addition, a first body region of a second conductivity type that is provided in the low-concentration impurity layer, and functions as a body region of the first vertical MOS transistor, the second conductivity type being different from the first conductivity type; a second body region of the second conductivity type that is provided in the low-concentration impurity layer, and functions as a body region of the second vertical MOS transistor; and a guard ring region of the second conductivity type that is provided in the low-concentration impurity layer, and functions as a guard ring of the first Schottky barrier diode may be further included. The first body region, the second body region, and the guard ring region may be separated from one another.

With the above-described configuration, it is possible to relatively easily make the breakdown voltage of the first vertical MOS transistor and the breakdown voltage of the second vertical MOS transistor equal to each other.

In addition, a second Schottky barrier diode that is connected in parallel with a body diode of the second vertical MOS transistor in a same forward direction may be further include. In the second Schottky barrier diode, the low-concentration impurity layer may serve as a cathode of the second Schottky barrier diode when the first conductivity type is n-type, and serve as an anode of the second Schottky barrier diode when the first conductivity type is p-type.

With the above-described configuration, compared to the case where the conventional dual-configuration semiconductor device is used alone, it is possible to reduce also the forward voltage between a node connected to the anode of the body diode of the other of the two vertical MOS transistors sharing a semiconductor substrate as a common drain region and a node connected to the cathode of the body diode of the other of the two vertical MOS transistors, without increasing the total number of elements.

In addition, an area of a region that forms a Schottky junction in the first Schottky barrier diode and an area of a region that forms a Schottky junction in the second Schottky barrier diode may be different from each other in a plan view of the semiconductor device.

With the above-described configuration, it is possible to make the characteristic of the first Schottky barrier diode and the characteristic of the second Schottky barrier diode different from each other.

Hereinafter, specific examples of a semiconductor device according to one aspect of the present disclosure will be described with reference to the drawings. Each of the embodiments described here shows one specific example of the present disclosure. The numerical values, shapes, structural components, the arrangement and connection of the structural components, steps (processes), and the processing order of the steps, for instance, described in the following embodiments are mere examples, and thus are not intended to limit the scope of the present disclosure. The drawings are schematically illustrated diagrams and do not necessarily give strict illustration. Throughout the drawings, the same numeral is given to substantially the same structural component, and redundant description will be omitted or simplified.

### Embodiment 1

Hereinafter, a semiconductor device according to Embodiment 1 will be described. The semiconductor device according to Embodiment 1 is a chip size package type semiconductor device that can be face-down mounted, and includes two vertical MOS transistors that share a semiconductor substrate as a common drain region.

Note that, here, the semiconductor device according to Embodiment 1 is described as a chip size package type semiconductor device that can be face-down mounted. However, the semiconductor device according to Embodiment 1 is not necessarily limited to a semiconductor device that can be face-down mounted or a chip size package type semiconductor device.

### Configuration of Semiconductor Device

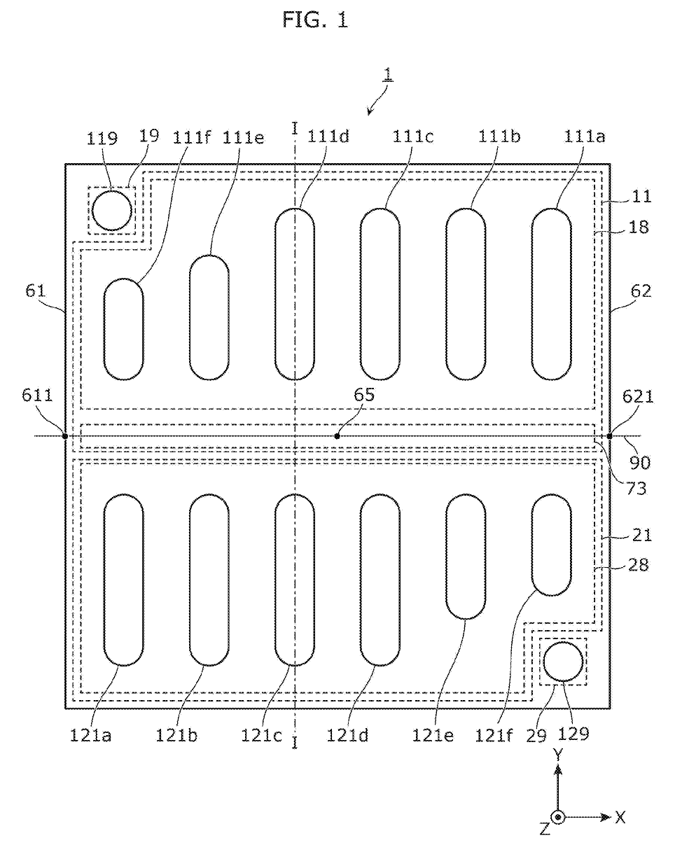

FIG. 1 is a plan view schematically illustrating an example of a configuration of semiconductor device 1 according to Embodiment 1.

In FIG. 1, the outer shapes of first electrode 11 (described later), second electrode 21 (described later), first gate electrode 19 (described later), second gate electrode 29 (described later), first body region 18 (described later), second body region 28 (described later), and first Schottky junction region 73 (described later) are indicated by the dashed lines as if they were directly visible from outside of semiconductor device 1. However, in reality, these outer shapes are not directly visible from outside of semiconductor device 1.

In Embodiment 1, as illustrated in FIG. 1, semiconductor device 1 is described assuming that semiconductor device 1 has a rectangular shape including first side 61 and second side 62 which are parallel to each other in a plan view of semiconductor device 1.

However, semiconductor device 1 is not necessarily limited to a configuration having a rectangular shape and including first side 61 and second side 62 which are parallel to each other in the plan view of semiconductor device 1. Note that the configuration of semiconductor device 1 having a rectangular shape and including first side 61 and second side 62 which are parallel to each other in the plan view of semiconductor device 1 also includes a configuration having a square shape in which the four sides are equal in length.

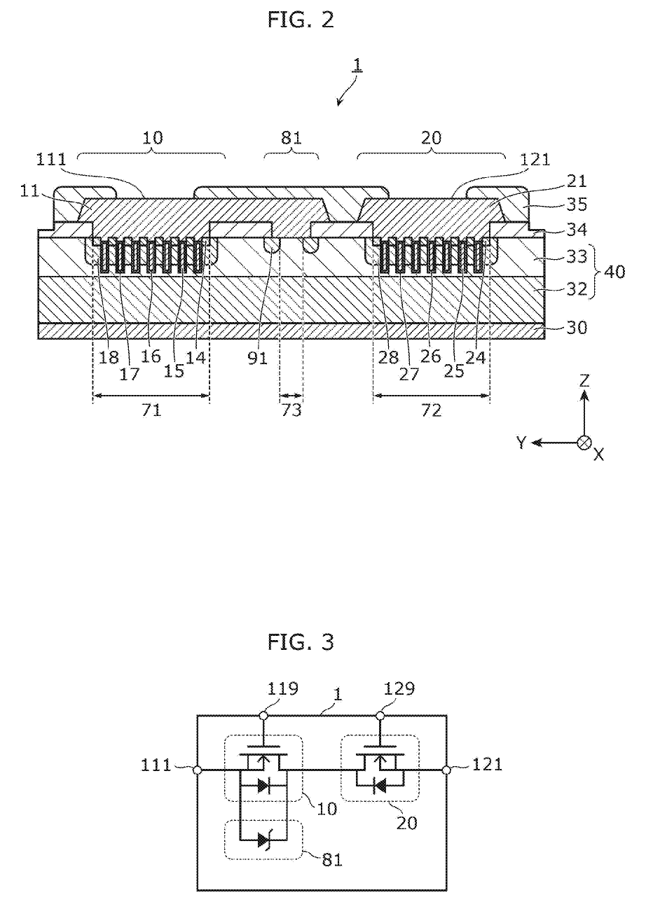

FIG. 2 is a cross-sectional view schematically illustrating an example of the configuration of semiconductor device 1. FIG. 2 illustrates a cut surface taken along line I-I of FIG. 1.

FIG. 3 is a circuit diagram of semiconductor device 1.

As illustrated in FIG. 1 to FIG. 3, semiconductor device 1 includes semiconductor layer 40, metal layer 30, oxide film 34, protective film 35, first electrode 11, second electrode 21, first gate electrode 19, second gate electrode 29, first vertical MOS transistor 10, second vertical MOS transistor 20, and first Schottky barrier diode 81.

In addition, semiconductor device 1 includes, on the top surface of semiconductor device 1, one or more first source pads 111 that function as source pads of first vertical MOS transistor 10, first gate pad 119 that functions as a gate pad of first vertical MOS transistor 10, one or more second source pads 121 that function as source pads of second vertical MOS transistor 20, and second gate pad 129 that functions as a gate pad of second vertical MOS transistor 20. The one or more first source pads 111 correspond to first source pad 111a to first source pad 111f illustrated in FIG. 1. Hereinafter, when there is no need to explicitly distinguish each one from one another, first source pad 111a to first source pad 111f may also be simply referred to as “first source pad 111”. The one or more second source pads 121 correspond to second source pad 121a to second source pad 121f illustrated in FIG. 1. Hereinafter, when there is no need to explicitly distinguish each one from one another, second source pad 121a to second source pad 121f may also be simply referred to as “second source pad 121”.

The one or more first source pads 111 may be oblong in shape in the plan view of semiconductor device 1, as a non-limiting example.

In addition, first gate pad 119 may be circular in shape in the plan view of semiconductor device 1, as a non-limiting example.

In addition, the one or more second source pads 121 may be oblong in shape in the plan view of semiconductor device 1, as a non-limiting example.

In addition, second gate pad 129 may be circular in shape in the plan view of semiconductor device 1, as a non-limiting example.

Here, as illustrated in FIG. 1, semiconductor device 1 is described as having a configuration in which, in the plan view of semiconductor device 1, the one or more first source pads 111 and the one or more second source pads 121 are positioned point-symmetrically with center 65 of semiconductor device 1 as the center of symmetry.

However, semiconductor device 1 is not necessarily limited to a configuration in which, in the plan view of semiconductor device 1, the one or more first source pads 111 and the one or more second source pads 121 are positioned point-symmetrically with center 65 of semiconductor device 1 as the center of symmetry.

As an example of the other configuration, for example, semiconductor device 1 may have a configuration in which, in the plan view of semiconductor device 1, the one or more first source pads 111 and the one or more second source pads 121 are positioned line-symmetrically with straight line 90 connecting midpoint 611 of first side 61 and midpoint 621 of second side 62 as the axis of symmetry.

Semiconductor device 1 has the configuration in which, in the plan view of semiconductor device 1, the one or more first source pads 111 and the one or more second source pads 121 are positioned point-symmetrically with center 65 of semiconductor device 1 as the center of symmetry, or positioned line-symmetrically with straight line 90 connecting midpoint 611 of first side 61 and midpoint 621 of second side 62 as the axis of symmetry. With this configuration, it is possible to inhibit the occurrence of defects such as a contact failure when mounting semiconductor device 1 on a mounting substrate.

In addition, as a non-limiting example, in order to uniformly control bidirectional conduction, in both the conduction direction from first vertical MOS transistor 10 toward second vertical MOS transistor 20 and the conduction direction from second vertical MOS transistor 20 toward first vertical MOS transistor 10, it is optional to arrange first vertical MOS transistor 10 and second vertical MOS transistor 20 symmetrically in the plan view of semiconductor device 1. In order to implement the symmetrical arrangement of first vertical MOS transistor 10 and second vertical MOS transistor 20 described above, as a non-limiting example, as illustrated in FIG. 1 and FIG. 2, first Schottky barrier diode 81 may be disposed in a region that includes center 65 of semiconductor device 1 and is interposed between first vertical MOS transistor 10 and second vertical MOS transistor 20 in the plan view of semiconductor device 1.

In addition, in order for semiconductor device 1 to have a configuration in which, in the plan view of semiconductor device 1, the one or more first source pads 111 and the one or more second source pads 121 are positioned point-symmetrically with center 65 of semiconductor device 1 as the center of symmetry, or positioned line-symmetrically with straight line 90 connecting midpoint 611 of first side 61 and midpoint 621 of second side 62 as the axis of symmetry, as described above, as a non-limiting example, it is optional that first Schottky barrier diode 81 is disposed in a region that includes center 65 of semiconductor device 1 and is interposed between first vertical MOS transistor 10 and second vertical MOS transistor 20 as illustrated in FIG. 1 and FIG. 2, and furthermore, the one or more first source pads 111 and the one or more second source pads 121 are arranged avoiding a region directly above first Schottky barrier diode 81 as illustrated in FIG. 1 and FIG. 2 (in this case, “directly above” means directly above when the positive direction of the Z-axis in FIG. 1 is taken as up).

Note that, in this Description, the center in a plan view refers to: for a structure that is rectangular in shape in the plan view such as semiconductor device 1, the intersection point of the diagonal lines of the rectangular shape; for a structure that is oblong in shape in a plan view such as first source pad 111 and second source pad 121, the intersection point of the axis of line symmetry extending in the longitudinal direction of the oblong shape and the axis of line symmetry extending in the lateral direction of the oblong shape; for a structure that is circular in shape in the plan view such as first gate pad 119 and second gate pad 129, the center of the circular shape; and for a structure that is oval in shape in the plan view, the intersection point of the major axis and the minor axis of the oval shape.

Semiconductor layer 40 is configured with semiconductor substrate 32 and low-concentration impurity layer 33 stacked on each other.

Semiconductor substrate 32 is made of silicon of a first conductivity type containing a first concentration of impurities.

Low-concentration impurity layer 33 is made of silicon of the first conductivity type that is provided in contact with a top surface of semiconductor substrate 32, and contains a second concentration of impurities. The second concentration is lower than the first concentration. For instance, low-concentration impurity layer 33 may be epitaxially grown on semiconductor substrate 32.

Typically, semiconductor conductivity types include the two conductivity types that are p-type and n-type. The first conductivity type may also be p-type or n-type. Here, for the convenience of explanation, the first conductivity type is described as n-type, and a second conductivity type, which is described later, is described as p-type. However, the first conductivity type may be p-type, and the second conductivity type may be n-type.

Metal layer 30 is provided in contact with a rear surface of semiconductor layer 40. Metal layer 30 may, as a non-limiting example, have a configuration in which one or more layers including a layer made of silver or copper. Note that metal layer 30 may contain, in trace amounts, non-metal elements that are incorporated as impurities during the manufacturing process of semiconductor device 1.

Oxide film 34 is provided in contact with a top surface of low-concentration impurity layer 33.

Protective film 35 is a protective film covering the top surfaces of oxide film 34, first electrode 11, second electrode 21, first gate electrode 19, and second gate electrode 29.

Protective film 35 includes one or more openings for exposing a portion of the top surface of first electrode 11 to outside protective film 35, one or more openings for exposing a portion of the top surface of second electrode 21 to outside protective film 35, an opening for exposing a portion of the top surface of first gate electrode 19 to outside protective film 35, and an opening for exposing a portion of the top surface of second gate electrode 29 to outside protective film 35.

The top surface of first electrode 11 is exposed to outside protective film 35 at one or more openings in protective film 35. The portions of the top surface of first electrode 11 exposed to outside protective film 35 at the one or more openings in protective film 35 serve as the one or more first source pads 111.

In other words, the one or more first source pads 111 are the portions of the top surface of first electrode 11 that are exposed to outside protective film 35 at the one or more openings.

The top surface of second electrode 21 is exposed to outside protective film 35 at one or more openings in protective film 35. The portions of the top surface of second electrode 21 exposed to outside protective film 35 at the one or more openings in protective film 35 serve as the one or more second source pads 121.

In other words, the one or more second source pads 121 are the portions of the top surface of second electrode 21 that are exposed to outside protective film 35 at the one of the openings.

The top surface of first gate electrode 19 is exposed to outside protective film 35 at an opening in protective film 35. The portion of the top surface of first gate electrode 19 exposed to outside protective film 35 at the opening in protective film 35 serves as first gate pad 119.

In other words, first gate pad 119 is the portion of the top surface of first gate electrode 19 that is exposed to outside protective film 35 at the opening.

The top surface of second gate electrode 29 is exposed to outside protective film 35 at an opening in protective film 35. The portion of the top surface of second gate electrode 29 exposed to outside protective film 35 at the opening in protective film 35 serves as second gate pad 129.

In other words, second gate pad 129 is the portion of the top surface of second gate electrode 29 that is exposed to outside protective film 35 at the opening.

First body region 18 that contains a third concentration of impurities and is a body region of the second conductivity type different from the first conductivity type is provided in low-concentration impurity layer 33 in a region within first electrode 11 in the plan view of semiconductor device 1.

In addition, a plurality of first gate trenches 17 are each provided at least partially in low-concentration impurity layer 33 in the region within first electrode 11 in the plan view of semiconductor device 1. The plurality of first gate trenches 17 extend in a first direction (the X-axis direction in FIG. 1 and FIG. 2) parallel to the top surface of semiconductor substrate 32, and are arranged at equal intervals in a second direction (the Y-axis direction in FIG. 1 and FIG. 2) perpendicular to the first direction and parallel to the top surface of semiconductor substrate 32. The plurality of first gate trenches 17 penetrate through first body region 18 from the top surface of low-concentration impurity layer 33 to reach a portion of low-concentration impurity layer 33.

First gate conductor 15 surrounded by first gate insulating film 16 and extends in the first direction is provided inside each of the plurality of first gate trenches 17.

First gate conductor 15 is electrically connected to first gate electrode 19.

First gate conductor 15 is polysilicon containing impurities, as a non-limiting example.

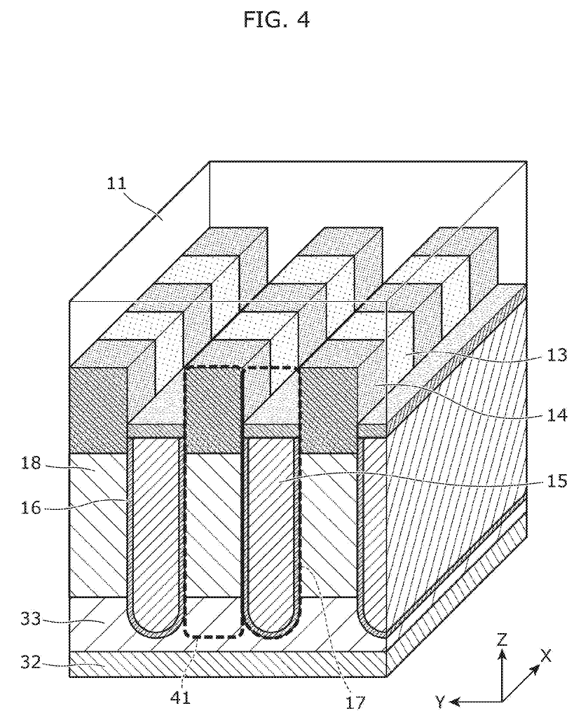

FIG. 4 is an enlarged cross-sectional perspective view schematically illustrating an example of a configuration around first gate trenches 17 in semiconductor device 1.

In FIG. 4, first electrode 11 is illustrated as if it were transparent. However, in reality, first electrode 11 is not transparent, and the structure behind first electrode 11 is not directly visible through first electrode 11.

As illustrated in FIG. 4, in low-concentration impurity layer 33, in each of a plurality of first mesa portions 41 interposed between the plurality of first gate trenches 17 in the second direction (the Y-axis direction in FIG. 4), a plurality of first source regions 14 and a plurality of first body contact regions 13 are arranged alternately one by one at first intervals in the first direction (the X-axis direction in FIG. 4). The plurality of first source regions 14 are each a source region of the first conductivity type that is provided in first mesa portion 41 and at the top surface thereof and contains a fourth concentration of impurities. The plurality of first body contact regions 13 are each a body contact region of the second conductivity type that is provided in first mesa portion 41 and at the top surface thereof and contains a fifth concentration of impurities. The fifth concertation is higher than the third concentration.

In other words, semiconductor device 1 further includes the plurality of first source regions 14 and the plurality of first body contact regions 13.

As illustrated in FIG. 2 and FIG. 4, first electrode 11 is in contact with and is connected to the plurality of first source regions 14 and the plurality of first body contact regions 13 within a region that does not include even a part of a portion that does not encompass first body region 18 in a plan view of semiconductor device 1.

Here, the fourth concentration that is the impurity concentration of first source region 14 is a concentration adjusted such that first electrode 11 and first source region 14 form an ohmic contact, and the fifth concentration of first body contact region 13 is a concentration adjusted such that first electrode 11 and first body contact region 13 form an ohmic contact.

Accordingly, first electrode 11 and first source region 14 form an ohmic contact, and first electrode 11 and first body contact region 13 form an ohmic contact.

In other words, as illustrated in FIG. 2, first electrode 11 includes first ohmic contact region 71 that forms an ohmic contact with the top surface of semiconductor layer 40 within a region that does not include even a part of a portion that does not encompass first body region 18 in the plan view of semiconductor device 1.

With the above-described configuration, semiconductor device 1 includes first vertical MOS transistor 10.

In addition, with the above-described configuration, first electrode 11 functions as the source electrode of first vertical MOS transistor 10.

In addition, with the above-described configuration, first gate electrode 19 functions as the gate electrode of first vertical MOS transistor 10.

Here, as illustrated in FIG. 2 and FIG. 4, the junction surface between first body region 18 and low-concentration impurity layer 33 in first vertical MOS transistor 10 is a PN junction surface.

As described above, first vertical MOS transistor 10 includes a body diode whose forward direction is the direction of the electrical path from first body region 18 to low-concentration impurity layer 33.

Second body region 28 that contains a third concentration of impurities and is a body region of the second conductivity type is provided in low-concentration impurity layer 33 in a region within second electrode 21 in the plan view of semiconductor device 1.

In addition, a plurality of second gate trenches 27 are each provided at least partially in low-concentration impurity layer 33 in the region within second electrode 21 in the plan view of semiconductor device 1. The plurality of second gate trenches 27 extend in the first direction and are arranged at equal intervals in the second direction. The plurality of second gate trenches 27 penetrate through second body region 28 from the top surface of low-concentration impurity layer 33 to reach a portion of low-concentration impurity layer 33.

Second gate conductor 25 surrounded by second gate insulating film 26 and extends in the first direction is provided inside each of the plurality of second gate trenches 27.

Second gate conductor 25 is electrically connected to second gate electrode 29.

Second gate conductor 25 is polysilicon containing impurities, as a non-limiting example.

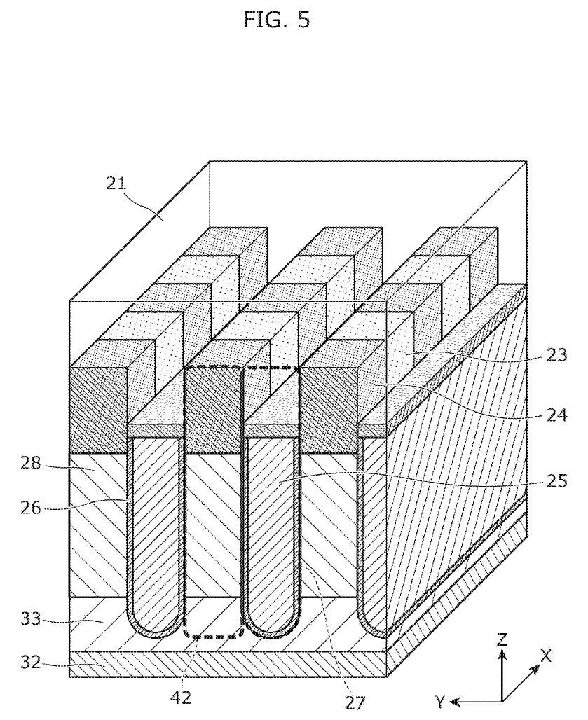

FIG. 5 is an enlarged cross-sectional perspective view schematically illustrating an example of a configuration around second gate trenches 27 in semiconductor device 1.

In FIG. 5, second electrode 21 is illustrated as if it were transparent. However, in reality, second electrode 21 is not transparent, and the structure behind second electrode 21 is not directly visible through second electrode 21.

As illustrated in FIG. 5, in low-concentration impurity layer 33, in each of a plurality of second mesa portions 42 interposed between the plurality of second gate trenches 27 in the second direction (the Y-axis direction in FIG. 5), a plurality of second source regions 24 and a plurality of second body contact regions 23 are arranged alternately one by one at first intervals in the first direction (the X-axis direction in FIG. 5). The plurality of second source regions 24 are each a source region of the first conductivity type that is provided in second mesa portion 42 and at the top surface thereof and contains the fourth concentration of impurities. The plurality of second body contact regions 23 are each a body contact region of the second conductivity type that is provided in second mesa portion 42 and at the top surface thereof and contains the fifth concentration of impurities.

In other words, semiconductor device 1 further includes the plurality of second source regions 24 and the plurality of second body contact regions 23.

As illustrated in FIG. 2 and FIG. 5, second electrode 21 is in contact with and is connected to the plurality of second source regions 24 and the plurality of second body contact regions 23 within a region that does not include even a part of a portion that does not encompass second body region 28 in the plan view of semiconductor device 1.

Here, the fourth concentration that is the impurity concentration of second source region 24 is a concentration adjusted such that second electrode 21 and second source region 24 form an ohmic contact, and the fifth concentration of second body contact region 23 is a concentration adjusted such that second electrode 21 and second body contact region 23 form an ohmic contact.

Accordingly, second electrode 21 and second source region 24 form an ohmic contact, and second electrode 21 and second body contact region 23 form an ohmic contact.

In other words, as illustrated in FIG. 2, second electrode 21 includes second ohmic contact region 72 that forms an ohmic contact with the top surface of semiconductor layer 40 within a region that does not include even a part of a portion that does not encompass second body region 28 in the plan view of semiconductor device 1.

With the above-described configuration, semiconductor device 1 includes second vertical MOS transistor 20.

In addition, with the above-described configuration, second electrode 21 functions as the source electrode of second vertical MOS transistor 20.

In addition, with the above-described configuration, second gate electrode 29 functions as the gate electrode of second vertical MOS transistor 20.

Here, as illustrated in FIG. 2 and FIG. 5, the junction surface between second body region 28 and low-concentration impurity layer 33 in second vertical MOS transistor 20 is a PN junction surface.

As described above, second vertical MOS transistor 20 includes a body diode whose forward direction is the direction of the electrical path from second body region 28 to low-concentration impurity layer 33.

With the above-described configuration, semiconductor substrate 32 functions as a common drain region in which the drain region of first vertical MOS transistor 10 and the drain region of second vertical MOS transistor 20 are commonized.

In other words, first vertical MOS transistor 10 and second vertical MOS transistor 20 share semiconductor substrate 32 as a common drain region.

Note that, here, semiconductor device 1 is described as having a configuration in which a total gate width of first vertical MOS transistor 10 and a total gate width of second vertical MOS transistor 20 are equal to each other.

For example, by making the configuration of first vertical MOS transistor 10 and the configuration of second vertical MOS transistor 20 similar to each other, it is possible to implement a configuration in which the total gate width of first vertical MOS transistor 10 and the total gate width of second vertical MOS transistor 20 are equal to each other.

In order to make the total gate width of first vertical MOS transistor 10 and the total gate width of second vertical MOS transistor 20 equal to each other, as a non-limiting example, it is optional that the area of first vertical MOS transistor 10 and the area of second vertical MOS transistor 20 are equal to each other in the plan view of semiconductor device 1.

Accordingly, as a non-limiting example, it is optional that semiconductor device 1 has a configuration in which, in a plan view of semiconductor device 1, a remaining region obtained by subtracting the region in which first Schottky barrier diode 81 is disposed from the entire region of semiconductor device 1 is bisected by area, with first vertical MOS transistor 10 disposed in one of the bisected regions and second vertical MOS transistor 20 disposed in the other of the bisected regions.

However, semiconductor device 1 not necessarily limited to having the configuration in which the total gate width of first vertical MOS transistor 10 and the total gate width of second vertical MOS transistor 20 are equal to each other.

As a result of semiconductor device 1 having a configuration in which the total gate width of first vertical MOS transistor 10 and the total gate width of second vertical MOS transistor 20 are equal to each other, it is possible to relatively easily make the characteristic of first vertical MOS transistor 10 and the characteristic of second vertical MOS transistor 20 equal to each other, and furthermore, in bidirectional conduction of the conduction direction from first vertical MOS transistor 10 toward second vertical MOS transistor 20 and the conduction direction from second vertical MOS transistor 20 toward first vertical MOS transistor 10, it is possible to inhibit current concentration and/or heat concentration from occurring disproportionately in either one of the vertical MOS transistors.

As illustrated in FIG. 1 and FIG. 2, in the plan view of semiconductor device 1, first electrode 11 is in contact with and is connected to low-concentration impurity layer 33 within a region that does not encompass even a part of first body region 18 and does not encompass even a part of second body region 28.

Here, the second concentration that is the impurity concentration of low-concentration impurity layer 33 is a concentration adjusted such that first electrode 11 and low-concentration impurity layer 33 form a Schottky junction.

Accordingly, first electrode 11 and low-concentration impurity layer 33 are caused to form a Schottky junction.

In other words, as illustrated in FIG. 1 and FIG. 2, first electrode 11 includes first Schottky junction region 73 that forms a Schottky junction with the top surface of semiconductor layer 40, within a region that does not encompass even a part of first body region 18 and does not encompass even a part of second body region 28 in the plan view of semiconductor device 1.

With the above-described configuration, semiconductor device 1 includes first Schottky barrier diode 81.

This first Schottky barrier diode 81 is a Schottky barrier diode in which low-concentration impurity layer 33 serves as a cathode and first electrode 11 serves as an anode.

As described above, first Schottky barrier diode 81 is a Schottky barrier diode that is connected in parallel with the body diode of first vertical MOS transistor 10 in the same forward direction.

With the above-described configuration, first electrode 11 functions as the anode electrode of first Schottky barrier diode 81 as well as functions as the source electrode of first vertical MOS transistor 10.

Note that, when the first conductivity type is p-type, first electrode 11 functions as the cathode electrode of first Schottky barrier diode 81 as well as functions as the source electrode of first vertical MOS transistor 10.

Here, as described above, semiconductor device 1 is described as having a configuration in which first electrode 11 functions as the anode electrode or the cathode electrode of first Schottky barrier diode 81 as well as functions as the source electrode of first vertical MOS transistor 10.

However, semiconductor device 1 is not necessarily limited to having the configuration in which first electrode 11 functions as the anode electrode or the cathode electrode of first Schottky barrier diode 81 as well as functions as the source electrode of first vertical MOS transistor 10.

As another configuration example, a configuration is conceivable in which, for example, semiconductor device 1 includes, as mutually different electrodes, an electrode that functions as a source electrode of first vertical MOS transistor 10 and an electrode that functions as an anode electrode or a cathode electrode of first Schottky barrier diode 81.

However, with such a configuration, it becomes necessary to newly provide a pad for externally connecting an electrode that functions as an anode electrode or a cathode electrode of first Schottky barrier diode 81, leading to an increase in the size of semiconductor device 1.

As a result of semiconductor device 1 having a configuration in which first electrode 11 functions as a source electrode of first vertical MOS transistor 10 as well as functions as an anode electrode or a cathode electrode of first Schottky barrier diode 81, it is possible to inhibit an increase in the size of semiconductor device 1 compared to a configuration in which an electrode that functions as a source electrode of first vertical MOS transistor 10 and an electrode that functions an anode electrode or a cathode electrode of first Schottky barrier diode 81 are provided as mutually different electrodes.

As illustrated in FIG. 2, in the plan view of semiconductor device 1, the outer periphery of first Schottky junction region 73 is surrounded by guard ring region 91 of the second conductivity type. Guard ring region 91 is provided in low-concentration impurity layer 33 and functions as a guard ring of first Schottky barrier diode 81.

In other words, semiconductor device 1 further includes guard ring region 91.

Here, as illustrated in FIG. 2, semiconductor device 1 is described as having a configuration in which first body region 18 of the second conductivity type, second body region 28 of the second conductivity type, and guard ring region 91 of the second conductivity type are separated from one another by low-concentration impurity layer 33 of the first conductivity type.

However, semiconductor device 1 is not necessarily limited to having the configuration in which first body region 18 of the second conductivity type, second body region 28 of the second conductivity type, and guard ring region 91 of the second conductivity type are separated from one another by low-concentration impurity layer 33 of the first conductivity type.

As a result of semiconductor device 1 having the configuration in which first body region 18 of the second conductivity type, second body region 28 of the second conductivity type, and guard ring region 91 of the second conductivity type are separated from one another by low-concentration impurity layer 33 of the first conductivity type, it is possible to relatively easily make the breakdown voltage of first vertical MOS transistor 10 and the breakdown voltage of second vertical MOS transistor 20 equal to each other.

If first body region 18 of the second conductivity type, second body region 28 of the second conductivity type, and guard ring region 91 of the second conductivity type were not separated from one another by low-concentration impurity layer 33 of the first conductivity type; that is, if, for example, first body region 18 of the second conductivity type and guard ring region 91 of the second conductivity type had portions overlapping each other, the impurity concentration of the second conductivity type in the overlapping portion would become higher than the impurity concentration of the second conductivity type in a non-overlapping portion.

For this reason, the electric field concentrates in the overlapping portion, and thus the breakdown voltage in the overlapping portion becomes weaker than the breakdown voltage in the non-overlapping portion.

As a result, the breakdown voltage of first vertical MOS transistor 10 and the breakdown voltage of first Schottky barrier diode 81 both decrease.

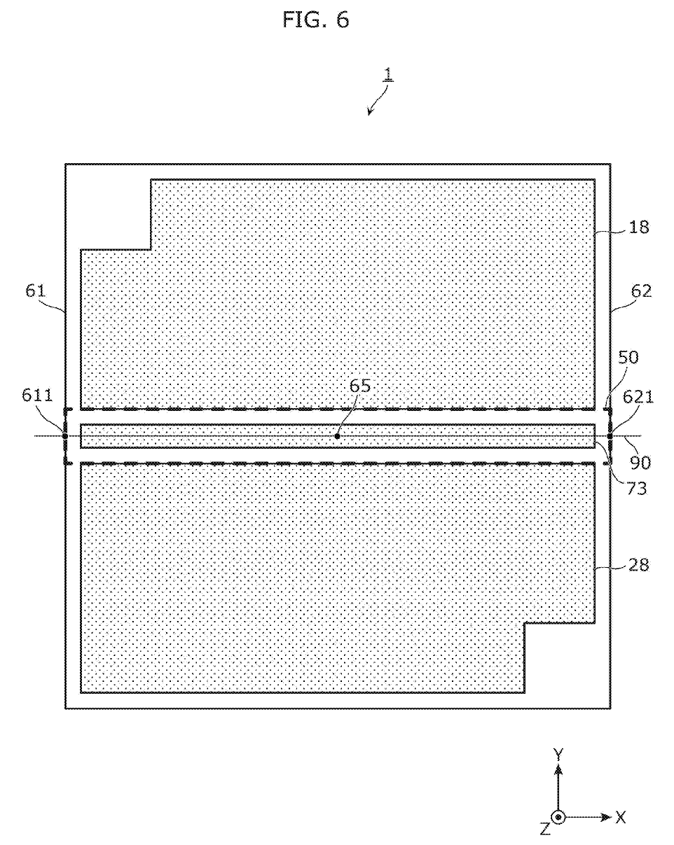

FIG. 6 is a plan view schematically illustrating a positional relationship between first body region 18, second body region 28, and first Schottky junction region 73.

In FIG. 6, the outer shapes of first body region 18, second body region 28, and first Schottky junction region 73 are indicated by the hatched solid lines as if they were directly visible from outside of semiconductor device 1. However, in reality, these outer shapes are not directly visible from outside of semiconductor device 1.

Here, as illustrated in FIG. 6, semiconductor device 1 is described as having a configuration including opposing region 50 that includes center 65 of semiconductor device 1, midpoint 611 of first side 61, and midpoint 621 of second side 62, and is continuous with a constant width from first side 61 to second side 62 in a plan view of semiconductor device 1. Opposing region 50 is located between first body region 18 and second body region 28 and does not encompass even a part of first body region 18 or second body region 28. The entirety of first Schottky junction region 73 is encompassed within opposing region 50; that is, the entirety of the region that forms a Schottky junction in first Schottky barrier diode 81 is encompassed within opposing region 50.

However, semiconductor device 1 is not necessarily limited to having the configuration in which: opposing region 50 which (i) includes center 65 of semiconductor device 1, midpoint 611 of first side 61, and midpoint 621 of second side 62, (ii) is continuous with a constant width from first side 61 to second side 62 in a plan view of semiconductor device 1, (iii) is located between first body region 18 and second body region 28, (iv) and does not encompass even a part of first body region 18 or second body region 28 is included; and the entirety of first Schottky junction region 73 is encompassed within opposing region 50.

As a result of semiconductor device 1 having the configuration in which: opposing region 50 which (i) includes center 65 of semiconductor device 1, midpoint 611 of first side 61, and midpoint 621 of second side 62, (ii) is continuous with a constant width from first side 61 to second side 62 in a plan view of semiconductor device 1, (iii) is located between first body region 18 and second body region 28, (iv) and does not encompass even a part of first body region 18 or second body region 28 is included; and the entirety of first Schottky junction region 73 is encompassed within opposing region 50, it is possible to relatively easily make the characteristic of first vertical MOS transistor 10 and the characteristic of second vertical MOS transistor 20 equal to each other.

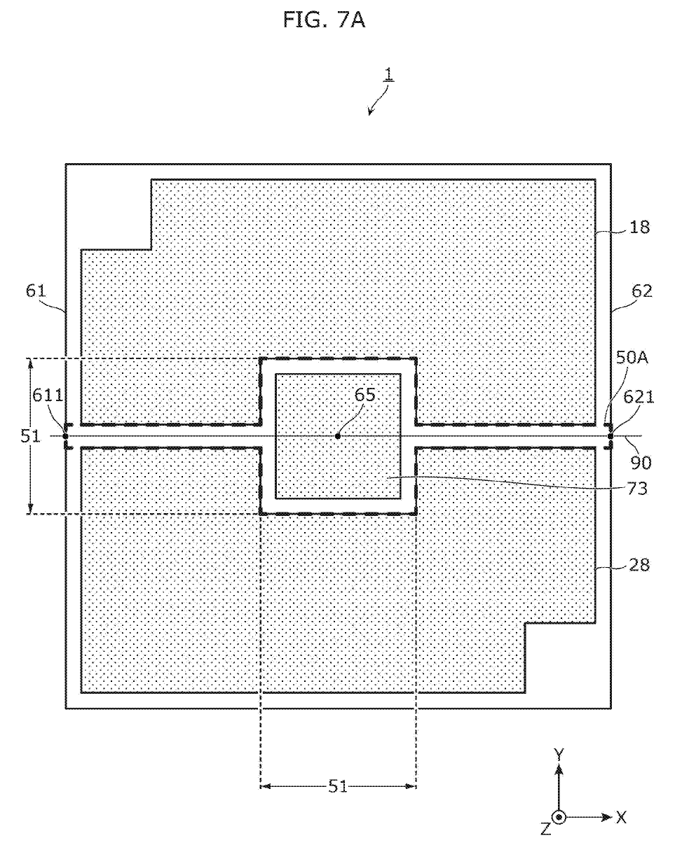

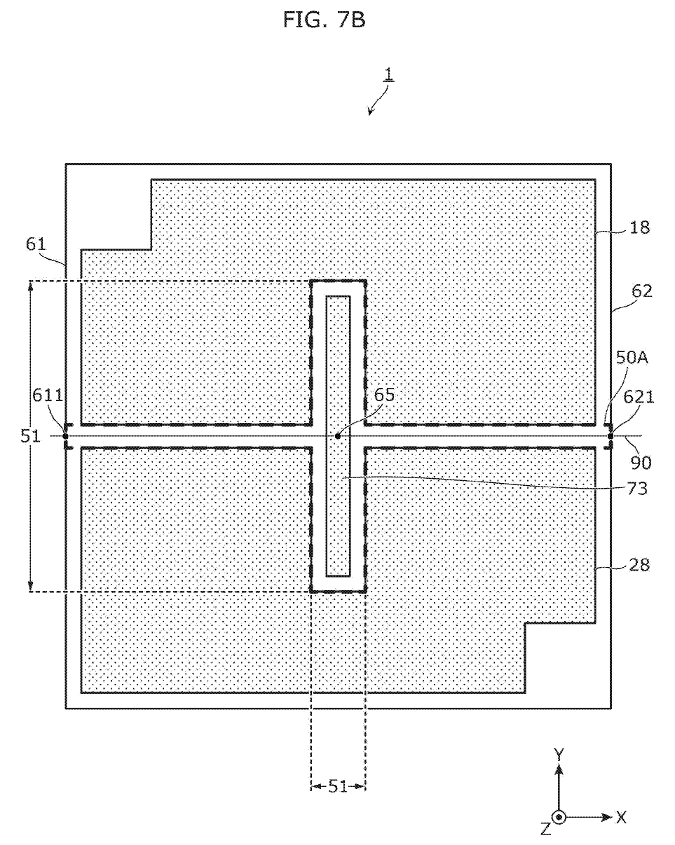

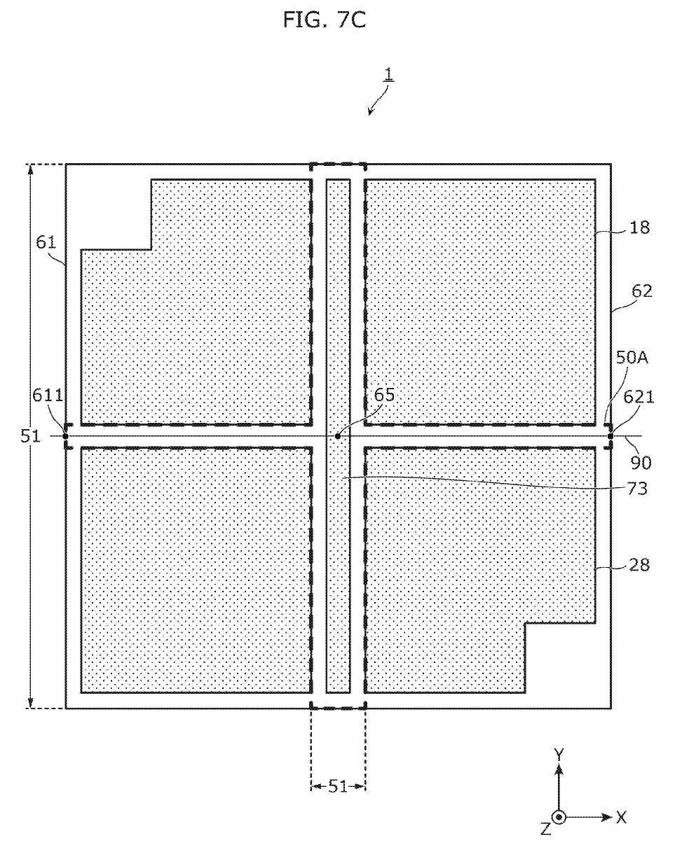

As an example of the other configuration, for example, semiconductor device 1 may have a configuration in which, as illustrated in FIG. 7A and FIG. 7B, opposing region 50A is included instead of including opposing region 50.

FIG. 7A and FIG. 7B are plan views each schematically illustrating a positional relationship between first body region 18, second body region 28, and first Schottky junction region 73, in the examples of the other configuration of semiconductor device 1.

In FIG. 7A and FIG. 7B, in the same manner as FIG. 6, the outer shapes of first body region 18, second body region 28, and first Schottky junction region 73 are indicated by the hatched solid lines as if they were directly visible from outside of semiconductor device 1. However, in reality, these outer shapes are not directly visible from outside of semiconductor device 1.

As illustrated in FIG. 7A and FIG. 7B, semiconductor device 1 may have a configuration in which: opposing region 50A which (i) includes center 65 of semiconductor device 1, midpoint 611 of first side 61, and midpoint 621 of second side 62, (ii) is continuous with a finite width from first side 61 to second side 62 in a plan view of semiconductor device 1, (iii) is located between first body region 18 and second body region 28, (iv) does not encompass even a part of first body region 18 or second body region 28, and (v) includes central region 51 whose width in a direction parallel to first side 61 and second side 62 is continuous with the maximum width of opposing region 50A in the direction is included; and the entirety of first Schottky junction region 73 is encompassed within central region 51; that is, the entirety of the region that forms a Schottky junction in first Schottky barrier diode 81 is encompassed within central region 51.

As a result of semiconductor device 1 having a configuration in which: opposing region 50A which (i) includes center 65 of semiconductor device 1, midpoint 611 of first side 61, and midpoint 621 of second side 62, (ii) is continuous with a finite width from first side 61 to second side 62 in a plan view of semiconductor device 1, (iii) is located between first body region 18 and second body region 28, (iv) does not encompass even a part of first body region 18 or second body region 28, and (v) includes central region 51 whose width in a direction parallel to first side 61 and second side 62 is continuous with the maximum width of opposing region 50A in the direction is included; and the entirety of first Schottky junction region 73 is encompassed within central region 51, it is possible to relatively easily make the characteristic of first vertical MOS transistor 10 and the characteristic of second vertical MOS transistor 20 equal to each other. Note that, as illustrated in FIG. 7C, the width of central region 51 in the direction parallel to first side 61 and second side 62 may be a width equal to the width of semiconductor device 1 in the direction parallel to first side 61 and second side 62.

FIG. 7C is a plan view schematically illustrating a positional relationship between first body region 18, second body region 28, and first Schottky junction region 73, in the example of the other configuration of semiconductor device 1.

In FIG. 7C, in the same manner as FIG. 6, FIG. 7A, and FIG. 7B, the outer shapes of first body region 18, second body region 28, and first Schottky junction region 73 are indicated by the hatched solid lines as if they were directly visible from outside of semiconductor device 1. However, in reality, these outer shapes are not directly visible from outside of semiconductor device 1.

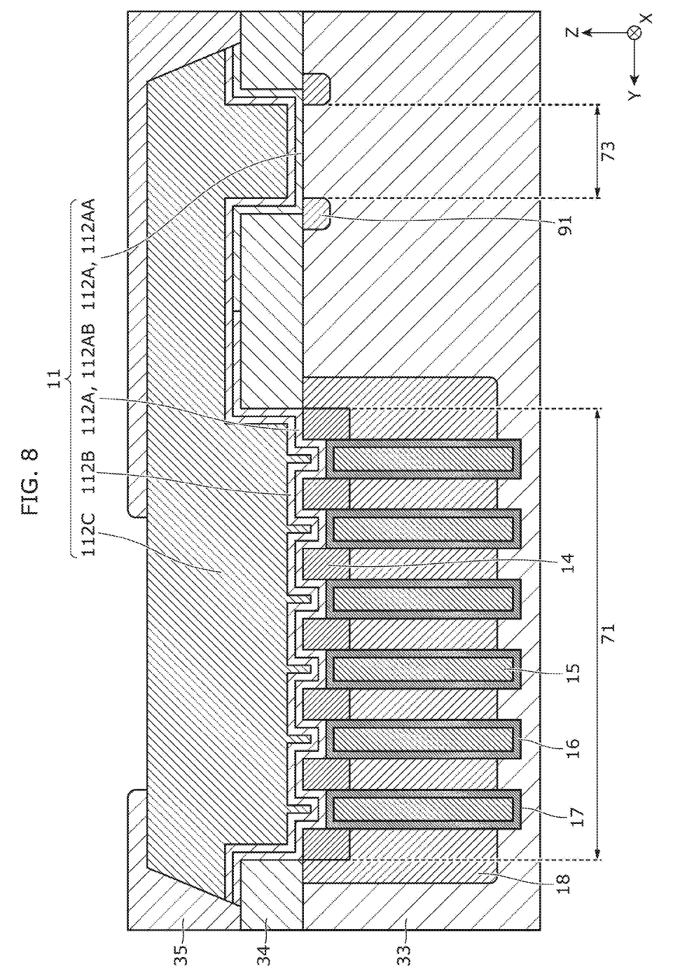

FIG. 8 is an enlarged cross-sectional view schematically illustrating an example of the configuration of first electrode 11.

Here, as illustrated in FIG. 8, first electrode 11 is described as having a configuration in which first conductive layer 112A, second conductive layer 112B, and third conductive layer 112C are included, and first conductive layer 112A, second conductive layer 112B, and third conductive layer 112C are stacked in stated order.

However, semiconductor device 1 is not necessarily limited to having the configuration in which first electrode 11 includes first conductive layer 112A, second conductive layer 112B, and third conductive layer 112C, and first conductive layer 112A, second conductive layer 112B, and third conductive layer 112C are stacked in stated order.

Third conductive layer 112C is a main structural component constituting the majority of first electrode 11, and is made of metal.

The metal is, for example, aluminum containing a small amount of copper as a non-limiting example.

First conductive layer 112A contains silicide and is in contact with and is connected to the top surface of semiconductor layer 40.

The thickness of first conductive layer 112A is, for example, from 5 nm to 50 nm as a non-limiting example.

As illustrated in FIG. 8, first conductive layer 112A, as a non-limiting example, may include Schottky junction layer 112AA that is in contact with and is connected to the top surface of semiconductor layer 40 (low-concentration impurity layer 33 in FIG. 8) in first Schottky junction region 73, and ohmic contact layer 112AB that is in contact with and is connected to the top surface of semiconductor layer 40 (low-concentration impurity layer 33 in FIG. 8) in first ohmic contact region 71.

In other words, first electrode 11 may include a plurality of metal layers including Schottky junction layer 112AA and ohmic contact layer 112AB.

In this case, the metal contained in Schottky junction layer 112AA and the metal contained in ohmic contact layer 112AB may be identical to each other, or may be different from each other.

When semiconductor device 1 has a configuration in which the metal contained in Schottky junction layer 112AA and the metal contained in ohmic contact layer 112AB are identical to each other, it is possible to more simplify the manufacturing process of semiconductor device 1 compared to the case where the metal contained in Schottky junction layer 112AA and the metal contained in ohmic contact layer 112AB are different from each other.

On the other hand, when semiconductor device 1 has a configuration in which the metal contained in Schottky junction layer 112AA and the metal contained in ohmic contact layer 112AB are different from each other, it is possible to enhance the characteristic of first Schottky barrier diode 81, compared to the case where the metal contained in Schottky junction layer 112AA and the metal contained in ohmic contact layer 112AB are identical to each other.

Second conductive layer 112B is a conductive layer interposed between first conductive layer 112A and third conductive layer 112C, and includes a barrier layer that inhibits diffusion of the components of third conductive layer 112C into semiconductor layer 40.

The barrier layer is made of, for example, titanium nitride, tantalum nitride, tungsten-titanium, tungsten-titanium nitride, ruthenium, cobalt, or the like, as a non-limiting example.

The thickness of second conductive layer 112B is, for example, from 10 nm to 100 nm as a non-limiting example.

### Observation

Semiconductor device 1 configured as above includes inside thereof two vertical MOS transistors (here, first vertical MOS transistor 10 and second vertical MOS transistor 20) that share semiconductor substrate 32 as a common drain region and first Schottky barrier diode 81 that is connected in parallel with the body diode of one of the vertical MOS transistors (here, first vertical MOS transistor 10) in the same forward direction.

As a result, according to semiconductor device 1 configured as above, a semiconductor device that is, compared to when the conventional dual-configuration semiconductor device is used alone, capable of reducing the forward voltage between a node connected to the anode of the body diode of one of the two vertical MOS transistors that share a semiconductor substrate as a common drain region and a node connected to the cathode of the body diode of the one of the two vertical MOS transistors, without increasing the total number of elements is provided.

Note that, in Embodiment 1, semiconductor device 1 has a configuration in which the Schottky barrier diode that is connected in parallel with the body diode of second vertical MOS transistor 20 in the same forward direction is not provided.

With the above-described configuration, it is possible to inhibit an increase in chip size, compared to the case of having the configuration in which the Schottky barrier diode that is connected in parallel with the body diode of second vertical MOS transistor 20 in the same forward direction is further provided.

Note that first Schottky barrier diode 81 included in semiconductor device 1 may be a junction barrier Schottky diode.

With this configuration, semiconductor device 1 is capable of inhibiting a leakage current in first Schottky barrier diode 81.

### Embodiment 2

The following describes a semiconductor device according to Embodiment 2 which has a configuration a part of which is changed from semiconductor device 1 according to Embodiment 1.

Semiconductor device 1 according to Embodiment 1 has a configuration in which first Schottky barrier diode 81 that is connected in parallel with the body diode of first vertical MOS transistor 10 in the same forward direction is provided, whereas the Schottky barrier diode that is connected in parallel with the body diode of second vertical MOS transistor 20 in the same forward direction is not provided.

In contrast, a semiconductor device according to Embodiment 2 has a configuration in which, in addition to including first Schottky barrier diode 81 that is connected in parallel with the body diode of first vertical MOS transistor 10 in the same forward direction, a Schottky barrier diode that is connected in parallel with the body diode of second vertical MOS transistor 20 in the same forward direction is provided.

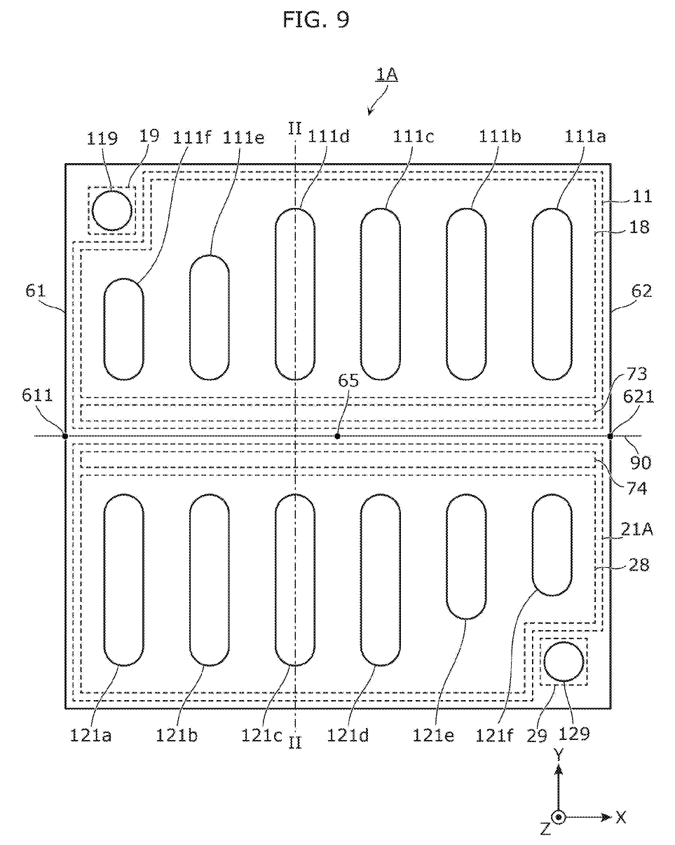

FIG. 9 is a plan view schematically illustrating an example of a configuration of semiconductor device 1A according to Embodiment 2.

In FIG. 9, the outer shapes of first electrode 11, second electrode 21A (described later), first gate electrode 19, second gate electrode 29, first body region 18, second body region 28, first Schottky junction region 73, and second Schottky junction region 74 (described later) are indicated by the dashed lines as if they were directly visible from outside of semiconductor device 1A. However, in reality, these outer shapes are not directly visible from outside of semiconductor device 1A.

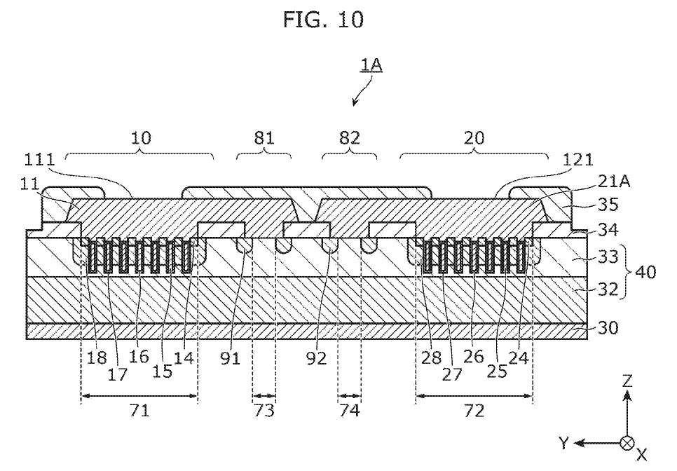

FIG. 10 is a cross sectional view schematically illustrating an example of the configuration of semiconductor device 1A. FIG. 10 illustrates a cut surface taken along line II-II of FIG. 9.

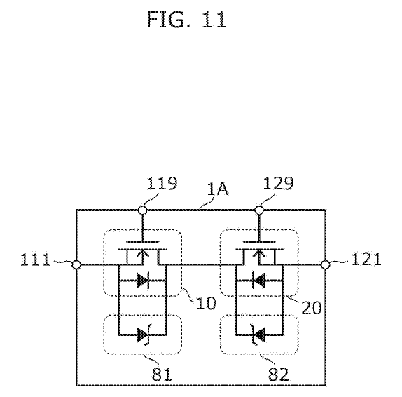

FIG. 11 is a circuit diagram of semiconductor device 1A.

As illustrated in FIG. 9 to FIG. 11, semiconductor device 1A is configured with second electrode 21 of semiconductor device 1 according to Embodiment 1 being changed to second electrode 21A, and second Schottky barrier diode 82 and guard ring region 92 being added.

As illustrated in FIG. 9 and FIG. 10, in the same manner as second electrode 21, second electrode 21A is in contact with and is connected to a plurality of second source regions 24 and a plurality of second body contact regions 23 within a region that does not encompass even a part of a portion that does not include second body region 28 in a plan view of semiconductor device 1A.

In other words, in the same manner as second electrode 21, second electrode 21A, as illustrated in FIG. 10, includes second ohmic contact region 72 that forms an ohmic contact with the top surface of semiconductor layer 40 within a region that does not include even a part of a portion that does not encompass second body region 28 in the plan view of semiconductor device 1A.

In addition, second electrode 21A is in contact with and is connected to low-concentration impurity layer 33 within a region that does not encompass even a part of first body region 18 and does not include even a part of second body region 28 in the plan view of semiconductor device 1A.

Here, the second concentration that is the impurity concentration of low-concentration impurity layer 33 is a concentration adjusted such that second electrode 21A and low-concentration impurity layer 33 form a Schottky junction.

Accordingly, second electrode 21A and low-concentration impurity layer 33 are caused to form a Schottky junction.

In other words, as illustrated in FIG. 9 and FIG. 10, second electrode 21A includes second Schottky junction region 74 that forms a Schottky junction with the top surface of semiconductor layer 40, within a region that does not encompass even a part of first body region 18 and does not encompass even a part of second body region 28 in the plan view of semiconductor device 1A.

With the above-described configuration, semiconductor device 1A includes second Schottky barrier diode 82.

This second Schottky barrier diode 82 is a Schottky barrier diode in which low-concentration impurity layer 33 serves as a cathode and second electrode 21A serves as an anode.

As described above, second Schottky barrier diode 82 is a Schottky barrier diode that is connected in parallel with the body diode of second vertical MOS transistor 20 in the same forward direction.

With the above-described configuration, second electrode 21A functions as the anode electrode of second Schottky barrier diode 82 as well as functions as the source electrode of second vertical MOS transistor 20.

In addition, as illustrated in FIG. 9, in the plan view of semiconductor device 1A, the outer periphery of second Schottky junction region 74 is surrounded by guard ring region 92 of the second conductivity type. Guard ring region 92 is provided in low-concentration impurity layer 33 and functions as a guard ring of second Schottky barrier diode 82.

In other words, semiconductor device 1A further includes guard ring region 92.

### Observation

Semiconductor device 1A configured as above includes inside thereof two vertical MOS transistors (here, first vertical MOS transistor 10 and second vertical MOS transistor 20) that share semiconductor substrate 32 as a common drain region and first Schottky barrier diode 81 that is connected in parallel with the body diode of one of the vertical MOS transistors (here, first vertical MOS transistor 10) in the same forward direction, and further includes second Schottky barrier diode 82 that is connected in parallel with the body diode of the other of the vertical MOS transistors (here, second vertical MOS transistor 20).

As a result, with semiconductor device 1A configured as above, it is possible to provide a semiconductor device that is, compared to when the conventional dual-configuration semiconductor device is used alone, capable of reducing the forward voltage between a node connected to the anode of the body diode of one of the two vertical MOS transistors sharing a semiconductor substrate as a common drain region and a node connected to the cathode of the body diode of the one of the two vertical MOS transistors, without increasing the total number of elements, and is further capable of reducing also the forward voltage between a node connected to the anode of the body diode of the other of the two vertical MOS transistors and a node connected to the cathode of the body diode of the other of the two vertical MOS transistors.

Note that, in FIG. 9, semiconductor device 1A is illustrated having a configuration in which, in the plan view of semiconductor device 1A, as if the area of first Schottky junction region 73 were same as the area of second Schottky junction region 74; that is, as if the area of the region that forms a Schottky junction in first Schottky barrier diode 81 were same as the area of the region that forms a Schottky junction in second Schottky barrier diode 82.

However, semiconductor device 1A may have a configuration in which the area of the region that forms a Schottky junction in first Schottky barrier diode 81 is same as the area of the region that forms a Schottky junction in second Schottky barrier diode 82 in the plan view of semiconductor device 1A, or may have a configuration in which the area of the region that forms a Schottky junction in first Schottky barrier diode 81 and the area of the region that forms a Schottky junction in second Schottky barrier diode 82 are different from each other in the plan view of semiconductor device 1A.

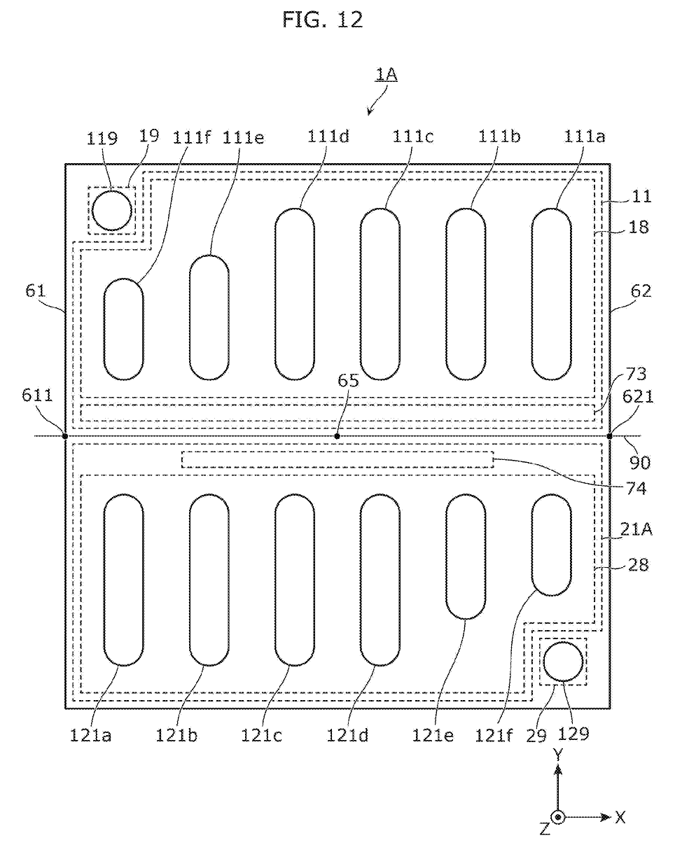

FIG. 12 is a plan view schematically illustrating an example of a configuration of semiconductor device 1A when the area of first Schottky junction region 73 and the area of second Schottky junction region 74 are different from each other in the plan view of semiconductor device 1A; that is, the area of the region that forms a Schottky junction in first Schottky barrier diode 81 and the area of the region that forms a Schottky junction in second Schottky barrier diode 82 are different from each other in the plan view of semiconductor device 1A.

As a result of semiconductor device 1A having a configuration in which the area of the region that forms a Schottky junction in first Schottky barrier diode 81 and the area of the region that forms a Schottky junction in second Schottky barrier diode 82 are different from each other in the plan view of semiconductor device 1A, it is possible to make the characteristic of first Schottky barrier diode 81 and the characteristic of second Schottky barrier diode 82 different from each other.

Note that since the control of the characteristic of a Schottky barrier diode can also be implemented by adjusting the area of the region that forms a Schottky junction, the above-described configuration of semiconductor device 1A is advantageous when the intended characteristic of a Schottky barrier diode differ between first Schottky barrier diode 81 and second Schottky barrier diode 82.

The semiconductor device according to one aspect of the present disclosure has been described above based on Embodiment 1 and Embodiment 2. However, the present disclosure is not limited to these embodiments. Various modifications of the above-described embodiments as well as embodiments resulting from combinations of structural components from different variations that may be conceived by those skilled in the art are intended to be included within the scope of the one or more aspects of the present disclosure, so long as these do not depart from the essence of the present disclosure.

### INDUSTRIAL APPLICABILITY

The present disclosure is broadly applicable to semiconductor devices, etc. that include a vertical MOS transistor.

1. A semiconductor device comprising:
a semiconductor layer including a semiconductor substrate of a first conductivity type and a low-concentration impurity layer of the first conductivity type, the semiconductor substrate containing a first concentration of an impurity, the low-concentration impurity layer being in contact with a top surface of the semiconductor substrate and containing a second concentration of an impurity, the second concentration being lower than the first concentration;
a first vertical metal-oxide-semiconductor (MOS) transistor and a second vertical MOS transistor that share the semiconductor substrate as a common drain region; and
a first Schottky barrier diode that is connected in parallel with a body diode of the first vertical MOS transistor in a same forward direction, wherein
a Schottky barrier diode that is connected in parallel with a body diode of the second vertical MOS transistor in a same forward direction is absent, and
in the first Schottky barrier diode, the low-concentration impurity layer serves as a cathode of the first Schottky barrier diode when the first conductivity type is n-type, and serves as an anode of the first Schottky barrier diode when the first conductivity type is p-type.

2. The semiconductor device according to claim 1, wherein
a total gate width of the first vertical MOS transistor and a total gate width of the second vertical MOS transistor are equal to each other.

3. The semiconductor device according to claim 2, further comprising:
a first electrode that functions as a source electrode of the first vertical MOS transistor, and functions (i) as an anode electrode of the first Schottky barrier diode when the first conductivity type is n-type and (ii) as a cathode electrode of the first Schottky barrier diode when the first conductivity type is p-type; and
a second electrode that functions as a source electrode of the second vertical MOS transistor, wherein
an area of the first electrode is larger than an area of the second electrode in a plan view of the semiconductor device.

4. The semiconductor device according to claim 3, further comprising, on a top surface of the semiconductor device:
one or more first source pads that function as source pads of the first vertical MOS transistor; and
one or more second source pads that function as source pads of the second vertical MOS transistor, the one or more second source pads being same in a total number as the one or more first source pads, wherein
the semiconductor device has a rectangular shape including a first side and a second side parallel to each other in the plan view, and
in the plan view, the one or more first source pads and the one or more second source pads are positioned point-symmetrically with a center of the semiconductor device as a center of symmetry, or positioned line-symmetrically with a straight line connecting a midpoint of the first side and a midpoint of the second side as an axis of symmetry.

5. The semiconductor device according to claim 3, further comprising:
a first body region of a second conductivity type that is provided in the low-concentration impurity layer, and functions as a body region of the first vertical MOS transistor, the second conductivity type being different from the first conductivity type, wherein
the first electrode includes:
a Schottky junction region that forms a Schottky junction with a top surface of the semiconductor layer within a region that does not encompass even a part of the first body region in the plan view; and
an ohmic contact region that forms an ohmic contact with the top surface of the semiconductor layer within a region that does not include even a part of a portion that does not encompass the first body region in the plan view,
the first electrode includes a plurality of conductive layers including (i) a Schottky junction layer that forms a Schottky junction with the top surface of the semiconductor layer in the Schottky junction region and (ii) an ohmic contact layer that forms an ohmic contact with the top surface of the semiconductor layer in the ohmic contact region, and
a metal contained in the Schottky junction layer and a metal contained in the ohmic contact layer are identical to each other.

6. The semiconductor device according to claim 3, further comprising
a first body region of a second conductivity type that is provided in the low-concentration impurity layer, and functions as a body region of the first vertical MOS transistor, the second conductivity type being different from the first conductivity type, wherein
the first electrode includes:
a Schottky junction region that forms a Schottky junction with a top surface of the semiconductor layer within a region that does not encompass even a part of the first body region in the plan view; and
an ohmic contact region that forms an ohmic contact with the top surface of the semiconductor layer within a region that does not include even a part of a portion that does not encompass the first body region in the plan view,
the first electrode includes a plurality of conductive layers including (i) a Schottky junction layer that forms a Schottky junction with the top surface of the semiconductor layer in the Schottky junction region and (ii) an ohmic contact layer that forms an ohmic contact with the top surface of the semiconductor layer in the ohmic contact region, and
a metal contained in the Schottky junction layer and a metal contained in the ohmic contact layer are different from each other.

7. The semiconductor device according to claim 3, wherein
the semiconductor device has a rectangular shape including a first side and a second side parallel to each other in the plan view, and
the semiconductor device further comprises: a first body region of a second conductivity type that is provided in the low-concentration impurity layer, and functions as a body region of the first vertical MOS transistor, the second conductivity type being different from the first conductivity type; and
a second body region of the second conductivity type that is provided in the low-concentration impurity layer, and functions as a body region of the second vertical MOS transistor; and
an opposing region that: includes a center of the semiconductor device, a midpoint of the first side, and a midpoint of the second side; and is continuous with a constant width from the first side to the second side in the plan view, the opposing region being located between the first body region and the second body region and not including even a part of the first body region or the second body region, and
an entirety of a region that forms a Schottky junction in the first Schottky barrier diode is encompassed within the opposing region in the plan view.

8. The semiconductor device according to claim 3, wherein
the semiconductor device has a rectangular shape including a first side and a second side parallel to each other in the plan view, and
the semiconductor device further comprises: a first body region of a second conductivity type that is provided in the low-concentration impurity layer, and functions as a body region of the first vertical MOS transistor, the second conductivity type being different from the first conductivity type;
a second body region of the second conductivity type that is provided in the low-concentration impurity layer, and functions as a body region of the second vertical MOS transistor; and
an opposing region that: includes a center of the semiconductor device, a midpoint of the first side, and a midpoint of the second side; and is continuous with a finite width from the first side to the second side in the plan view, the opposing region being located between the first body region and the second body region and not including even a part of the first body region or the second body region,
the opposing region includes a central region whose width in a direction parallel to the first side and the second side is continuous with a maximum width of the opposing region in the direction, and
an entirety of a region that forms a Schottky junction in the first Schottky barrier diode is encompassed within the central region.

9. The semiconductor device according to claim 3, further comprising:
a first body region of a second conductivity type that is provided in the low-concentration impurity layer, and functions as a body region of the first vertical MOS transistor, the second conductivity type being different from the first conductivity type;
a second body region of the second conductivity type that is provided in the low-concentration impurity layer, and functions as a body region of the second vertical MOS transistor; and
a guard ring region of the second conductivity type that is provided in the low-concentration impurity layer, and functions as a guard ring of the first Schottky barrier diode, wherein
the first body region, the second body region, and the guard ring region are separated from one another.

10. A semiconductor device comprising:
a semiconductor layer including a semiconductor substrate of a first conductivity type and a low-concentration impurity layer of the first conductivity type, the semiconductor substrate containing a first concentration of an impurity, the low-concentration impurity layer being in contact with a top surface of the semiconductor substrate and containing a second concentration of an impurity, the second concentration being lower than the first concentration;
a first vertical metal-oxide-semiconductor (MOS) transistor and a second vertical MOS transistor that share the semiconductor substrate as a common drain region;
a first Schottky barrier diode that is connected in parallel with a body diode of the first vertical MOS transistor in a same forward direction; and
a second Schottky barrier diode that is connected in parallel with a body diode of the second vertical MOS transistor in a same forward direction, wherein
an area of a region that forms a Schottky junction in the first Schottky barrier diode and an area of a region that forms a Schottky junction in the second Schottky barrier diode are different from each other in a plan view of the semiconductor device,
in the first Schottky barrier diode, the low-concentration impurity layer serves as a cathode of the first Schottky barrier diode when the first conductivity type is n-type, and serves as an anode of the first Schottky barrier diode when the first conductivity type is p-type, and
in the second Schottky barrier diode, the low-concentration impurity layer serves as a cathode of the second Schottky barrier diode when the first conductivity type is n-type, and serves as an anode of the second Schottky barrier diode when the first conductivity type is p-type.
